(19) United States
(12) Patent Application Publication
(10) Pub. No.: US 2014/0347870 A1
(43) Pub. Date: Nov. 27, 2014

(54) FLEXIBLE PRINTED CIRCUIT BOARD AND CIRCUIT BOARD ASSEMBLY HAVING THE SAME

(71) Applicants: Inventec (Pudong) Technology Corporation, Shanghai (CN); INVENTEC CORPORATION, Taipei (TW)

(72) Inventors: Yu-Chi CHO, Taipei (TW); Jung-Nan CHIEN, Taipei (TW); Shao-Wen CHIEN, Taipei (TW); Chieh-Hsiung LEE, Taipei (TW); Ching-Mei KUO, Taipei (TW)

(73) Assignees: Inventec (Pudong) Technology Corporation, Shanghai (CN); INVENTEC CORPORATION, Taipei (TW)

(21) Appl. No.: 14/246,902

(22) Filed: Apr. 7, 2014

(30) Foreign Application Priority Data
May 24, 2013 (CN) 201310198879.0

(51) Int. Cl. H05K 1/02; F21V 21/14

(52) U.S. Cl. CPC H05K 1/028; F21V 21/14; H05K 1/181
USPC 362/418; 174/254

(57) ABSTRACT

A circuit board assembly includes a substrate, a flexible printed circuit board and an electrical component. The substrate includes a first electrically connecting port. The flexible printed circuit board includes a main body and a branch body. The main body includes two second electrically connecting ports opposite to each other. One of the two second electrically connecting ports is electrically connected to the first electrically connecting port. One end of the branch body is connected to the main body. Another end of the branch body is disposed with an additional electrically connecting port. The electrical component is disposed on and electrically connected to the additional electrically connecting port. The electrical component is electrically connected to the substrate via the flexible printed circuit board.

### CROSS-REFERENCE TO RELATED APPLICATIONS

This non-provisional application claims priority under 35 U.S.C. §119(a) on Patent Application No(s). 201310198879.0 filed in China on May 24, 2013, the entire contents of which are hereby incorporated by reference.

### BACKGROUND OF THE INVENTION

1. Technical Field of the Invention

The disclosure relates to a circuit board assembly, in particularly to a circuit board assembly including a flexible printed circuit board.

2. Description of the Related Art

With the developments of the economy and the improvements of the standards of living, consumers not only demand basic functions of portable electronic devices, but also demand multi-functions and good appearance of the portable electronic devices.

In order to comply with the demand of the consumers for the portable electronic devices, current manufacturers have developed a slim and light circuit board assembly by combining a flexible printed circuit (FPC) with a hard printed circuit board (PCB). Moreover, the manufacturers have disposed a sub-circuit board and a cable wire. The sub-circuit board, disposed on a position near a button, includes a light emitting diode. The sub-circuit board is connected to the PCB through the cable wire. However, in order to make the button have a lighting function, the material cost (the sub-circuit board and the cable wire) is inevitably increased. Therefore, how to make the button have a lighting function as well as avoiding increasing the material cost is a problem that manufacturers try to solve.

### SUMMARY OF THE INVENTION

An embodiment of the disclosure provides a circuit board assembly comprising a substrate, a flexible printed circuit board and an electrical component. The substrate includes a first electrically connecting port. The flexible printed circuit board comprises a main body and a branch body. The main body includes two second electrically connecting ports opposite to each other. One of the two second electrically connecting ports is electrically connected to the first electrically connecting port. One end of the branch body is connected to the main body. Another end of the branch body is disposed with an additional electrically connecting port. The electrical component is disposed on and electrically connected to the additional electrically connecting port. The electrical component is electrically connected to the substrate via the flexible printed circuit board.

Another embodiment of the disclosure provides a flexible printed circuit board comprising a main body and a branch body. The main body includes two electrically connecting ports opposite to each other. One end of the branch body is connected to the main body. Another end of the branch body is disposed with an additional electrically connecting port.

### BRIEF DESCRIPTION OF THE DRAWINGS

The disclosure will become more fully understood from the detailed description given herein below for illustration only, thus does not limit the disclosure, wherein:

FIG. 1 is a schematic perspective view of a circuit board assembly disposed on a casing according to a first embodiment of the disclosure;

FIG. 2 is a schematic perspective view of a substrate in FIG. 1; and

FIG. 3 is a schematic plane view of a flexible printed circuit board in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

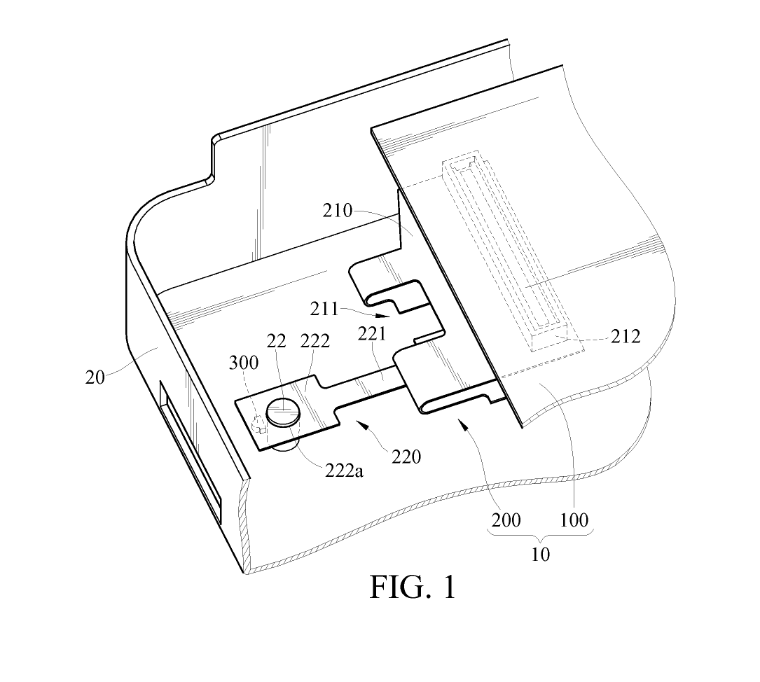

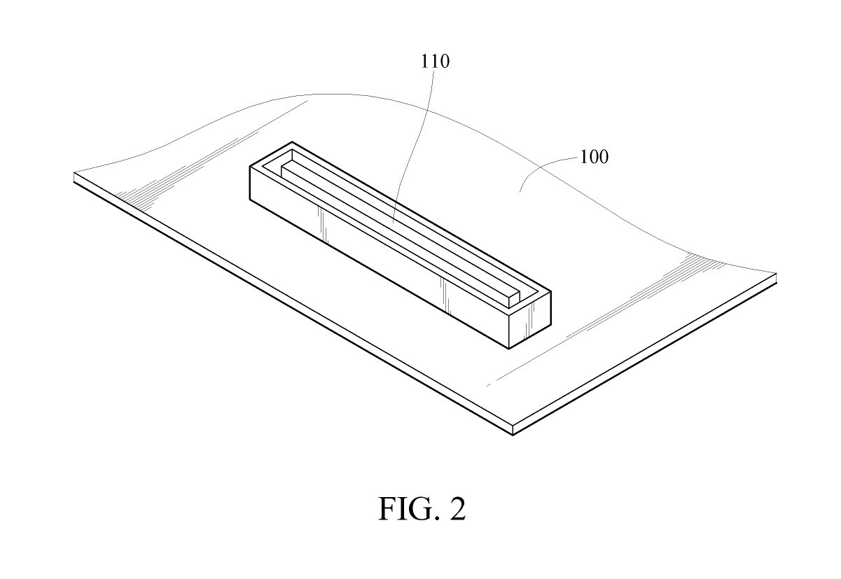

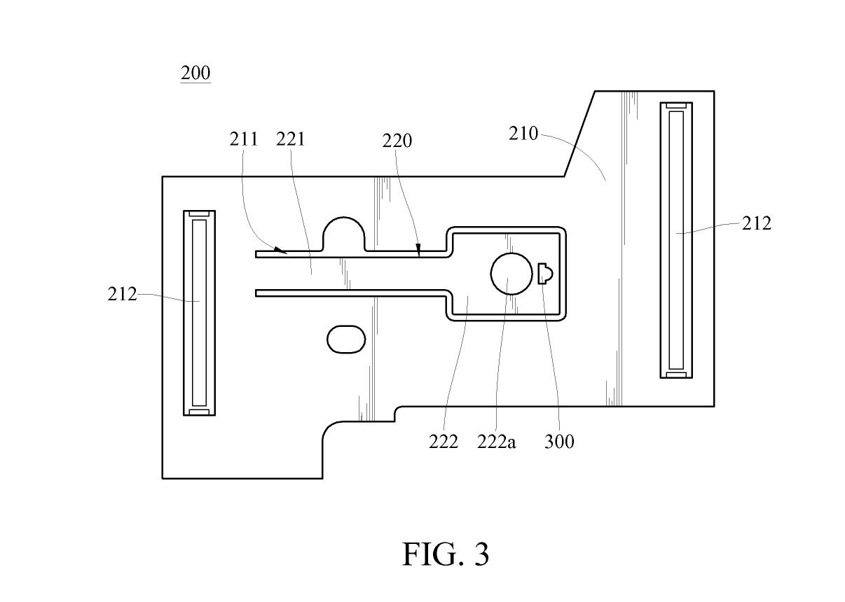

Please refer to FIGS. 1 to 3 together. FIG. 1 is a schematic perspective view of a circuit board assembly disposed on a casing according to a first embodiment of the disclosure, FIG. 2 is a schematic perspective view of a substrate in FIG. 1, and FIG. 3 is a schematic plane view of a flexible printed circuit board in FIG. 1.

The above-mentioned casing 20 includes a positioning post 22.

The circuit board assembly 10, according to this embodiment, includes a substrate 100, a flexible printed circuit board 200 and an electrical component 300. The substrate 100 includes a first electrically connecting port 110. In this embodiment, for example, the substrate 100 is a hard printed circuit board (PCB).

The flexible printed circuit board 200 is a flexible printed circuit (FPC). Moreover, the flexible printed circuit board 200 comprises a main body 210 and a branch body 220. The main body 210 includes an opening 211 and two second electrically connecting ports 212 that are opposite to each other. The opening 211 is located between the two second electrically connecting ports 212. One of the two second electrically connecting ports 212 is electrically connected to the first electrically connecting port 110 of the substrate 100. The other second electrically connecting port 212 is adapted for being electrically connected to another circuit board (not shown). One end of the branch body 220 is connected to the main body 210, and another end of the branch body 220 is disposed with an additional electrically connecting port 222. The branch body 220 includes a linking portion 221. The linking portion 221 is electrically connected to the main body 210. The additional electrically connecting port 222 is electrically connected to the linking portion 221. The additional electrically connecting port 222 includes a positioning hole 222a. The positioning hole 222a is sleeved on the positioning post 22 of the casing 20. In this embodiment, the branch body 220, located in the opening 211, is connected to the main body 210. In other embodiments, the branch body 220 is directly connected to a side of the main body 210.

In this embodiment, the main body 210 and the branch body 220 are integrally formed with each other. That is, the main body 210 and the branch body 220 are integrally formed into one piece. For example, the flexible printed circuit board 200 is manufactured by a stamping process to integrally form the main body 210 and the branch body 220, but is not limited to the disclosure. In other embodiments, the flexible printed circuit board 200 is manufactured by a laser cutting process to integrally form the main body 210 and the branch body 220.

The electrical component 300 is disposed on and electrically connected to the additional electrically connecting port 222. Moreover, the electrical component 300 is electrically connected to the substrate 100 via the flexible printed circuit board 200. For example, the electrical component 300 is a light emitting diode (LED).

In this embodiment, the flexible printed circuit board 200 includes not only the second electrically connecting port 212 for being electrically connected to the first electrically connecting port 110, but also the additional electrically connecting port 222 disposed on the branch body 220, such that the electrical component 300, disposed on the additional electrically connecting port 222, is electrically connected to the substrate 100 via circuits on the branch body 220 and the main body 210. Therefore, the electrical component 300 does not need another circuit board or cable for being electrically connected to the substrate 100, thereby reducing the material and assembly costs of the circuit board assembly 10.

According to the flexible printed circuit board and the circuit board assembly having the same, the branch body which includes the additional electrically connecting port is disposed on the flexible printed circuit board, such that another electrical component is electrically connected to the substrate via the circuits on the branch body and the main body. Therefore, the material cost of the circuit board and the cable is decreased, thereby reducing the material and assembly costs of the circuit board assembly.

What is claimed is:

1. A circuit board assembly, comprising:
a substrate including a first electrically connecting port;
a flexible printed circuit board comprising a main body and a branch body, the main body including two second electrically connecting ports opposite to each other, one of the two second electrically connecting ports being electrically connected to the first electrically connecting port, one end of the branch body being connected to the main body, and another end of the branch body being disposed with an additional electrically connecting port; and
an electrical component disposed on and electrically connected to the additional electrically connecting port, and the electrical component being electrically connected to the substrate via the flexible printed circuit board.

2. The circuit board assembly according to claim 1, wherein the branch body includes a linking portion, the linking portion is electrically connected to the main body, and the additional electrically connecting port is electrically connected to the linking portion.

3. The circuit board assembly according to claim 2, wherein the main body includes an opening, the branch body is located in the opening, and the linking portion is electrically connected to the main body.

4. The circuit board assembly according to claim 1, wherein the main body and the branch body are integrally formed with each other.

5. The circuit board assembly according to claim 1, wherein the electrical component is a light emitting diode.

6. The circuit board assembly according to claim 1, wherein the additional electrically connecting port includes a positioning hole.

7. A flexible printed circuit board, comprising:
a main body including two electrically connecting ports opposite to each other; and
a branch body, one end of the branch body being connected to the main body, and another end of the branch body being disposed with an additional electrically connecting port.

8. The flexible printed circuit board according to claim 7, wherein the main body and the branch body are integrally formed with each other.

9. The flexible printed circuit board according to claim 7, wherein the additional electrically connecting port includes a positioning hole.

10. The flexible printed circuit board according to claim 7, wherein the main body includes an opening, the branch body is located in the opening, the branch body includes a linking portion, the linking portion is electrically connected to the main body, and the additional electrically connecting port is connected to the linking portion.
